(19) United States
(12) Patent Application Publication
(10) Pub. No.: US 2005/0266656 A1
(43) Pub. Date: Dec. 1, 2005

(54) Method for producing a multilayer storage media

(76) Inventor: Bernd Heinz, Buchs (CH)

Correspondence Address: PEARNE & GORDON LLP, 1801 EAST 9TH STREET, SUITE 1200, CLEVELAND, OH, 44114-3108, US

(21) Appl. No.: 11/129,896

(22) Filed: May 16, 2005

Related U.S. Application Data
(60) Provisional application No. 60/572,194, filed on May 18, 2004.

(51) Int. Cl. H01L 21/46

(52) U.S. Cl. 438/455; 438/781

(57) ABSTRACT

An inventive method for producing a disc shaped workpiece comprises the steps of producing a first and a second disc-shaped substrate, applying a first adhesive at least partially onto one of the flat sides of said first substrate, curing said first adhesive, applying a second adhesive at least partially onto at least one of the flat sides of said first or second substrate and bonding said substrates to form said disc shaped workpiece.

This invention concerns optical data storage media, especially in optical disc production, such as DVD-14/18, DVD R DL and other multilayer media.

### BACKGROUND OF THE INVENTION

The common way to produce a dual layer single side DVD (like a DVD-9) is to bond two 0.6 mm substrates together, each of which is carrying an information layer. Another way to manufacture a double layer disk is the so called “2P process”. Instead of forming one layer in each (two) substrate, the 2P process gives rise to a single substrate structure with two internal information layers. This is not necessary for DVD-9 production, but for other multilayer formats like DVD14/18 or DVDR9.

### RELATED ART

U.S. Pat. No. 6,117,284 and U.S. Pat. No. 6,309,496 describe general information relating to the 2P process.

In the first step of the 2P process a first substrate with an information layer is produced by injection moulding and coated with a layer material which is appropriate for the format. Then a second substrate is produced with a second information layer. This second substrate is then bonded together with the first substrate using typically an UV-curing adhesive. In the next step the 2 (bonded) substrates are separated whereby the UV resin with the image of the information layer of the second substrate must remain completely at the first substrate. Depending on the application it is also possible to transfer a metallic layer in a similar way from the second to the first substrate.

For a good stamping result and an easy separation, the choice of materials of the UV-curing adhesive and of the second substrate is important. Whereas polycarbonate is typically used for the first substrate, PMMA or other non-polar materials are used for the second substrate.

However, the UV curing adhesive used between the first and second substrate has to fulfil several requirements. On the one hand the material should give good stamping results, one the other hand the material should exert minimal mechanical stress on the first substrate after the separation process to avoid a bending of this substrate. A certain amount of stress will be unavoidable due to the shrinkage process usually occurring during curing.

Due to the difficulty to achieve good replication and minimal bending with one curing adhesive the bonding layer can be produced by using 2 different adhesives. One with optimised elastic properties will be coated onto the first substrate and a second one, optimised for replication properties, will be coated onto the second substrate. Preferably the thickness ratio of the first and second adhesive should be unequal. The thickness of the first adhesive has to be maximised to avoid the unwanted contribution of the second adhesive to the bending of the substrate which is increasing with increasing thickness. To give an example: The required thickness of a bonding layer for DVD R DL media is 50 μm, this can be produced by bringing 40 μm of the first adhesive onto the first substrate and 10 μm of the second adhesive onto the second substrate and bond them together (see e.g. FIG. 1).

In state-of-the-art experiments, as described e.g. in U.S. Pat. No. 6,136,133, the two adhesives are brought onto the substrates at the same time and then they are bonded together using one curing step. This method requires only few process steps but has some disadvantages. High reliability of the bonding process and cleanness of the outer edge of the disc is difficult to achieve when using a first and a second adhesive with significant different thicknesses.

### BRIEF DESCRIPTION OF THE DRAWINGS

FIG. 1 shows a Prior Art situation of a bonding process

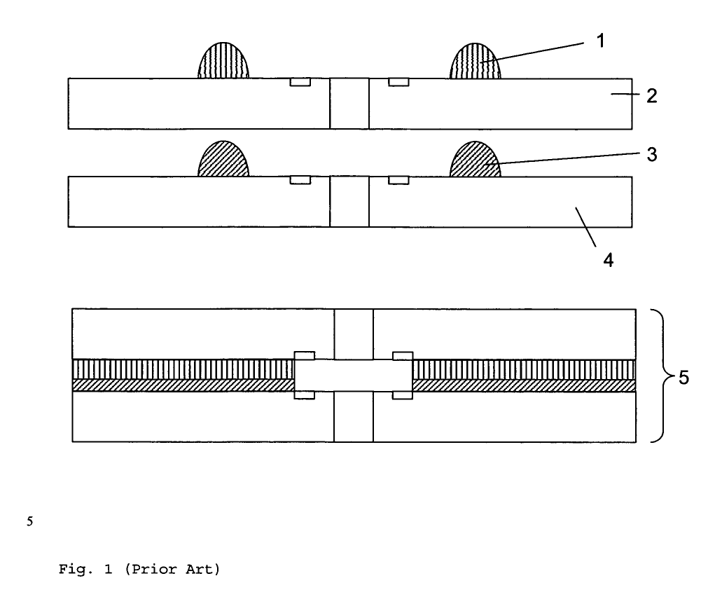

FIG. 2 shows one embodiment of the inventive process.

### SUMMARY OF THE INVENTION

To avoid the disadvantage of the state of the art solution for the 2P process with two different adhesives, the following method is suggested. A first adhesive, preferably one with the good replication properties, is spin-coated onto the adequate substrate and cured with UV-light in a first curing step. In the next step this coated substrate is bonded together with the remaining substrate using the second adhesive. This step is a standard bonding step finished by a second curing step.

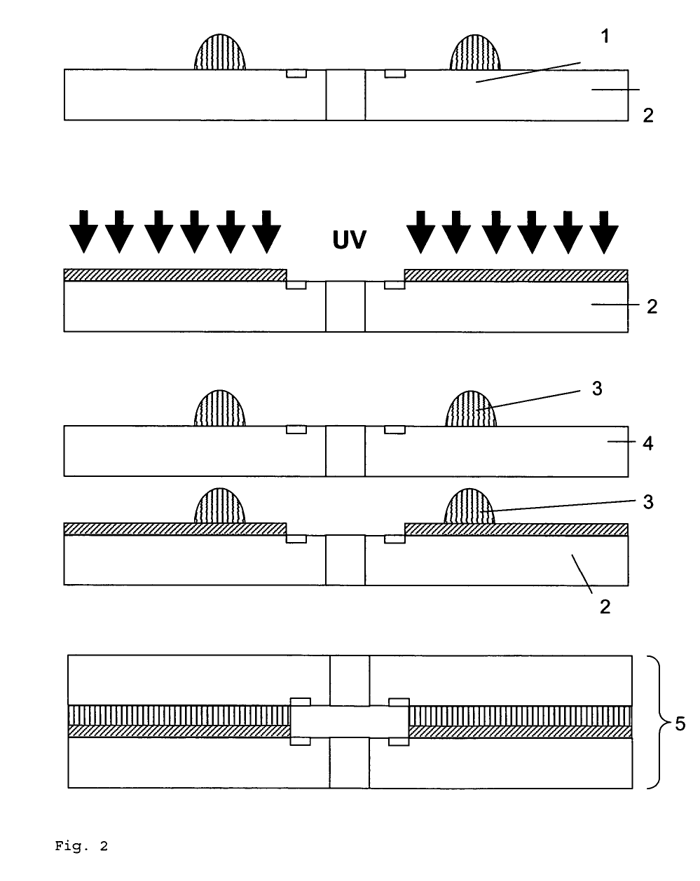

With the aid of FIG. 2 a preferred embodiment is being shown in detail. An inventive method for producing a disc shaped workpiece comprises the steps of producing a first and a second disc-shaped substrate, applying a first adhesive 1 at least partially onto one of the flat sides of said first substrate 2, curing said first adhesive, applying a second adhesive 3 at least partially onto at least one of the flat sides of said first 2 or second substrate 4 and bonding said substrates to form said disc shaped workpiece 5. Later said disc shaped workpiece may be cured again.

The invention divides the task of making a composite bonding layer into two steps which can be well controlled, the coating process and the bonding process. Thereby the process problems connected with the existing method are solved. The reliability of the bonding process and the cleanness of the outer edge of the finished disk will be increased.

### REFERENCE NUMERALS

1 first adhesive
2 first substrate
3 second adhesive
4 second substrate
5 bonded state, disc shaped workpiece

1. A Method for producing a disc shaped workpiece comprising the steps of:
a) Producing a first and a second disc-shaped substrate
b) Applying a first adhesive at least partially onto one of the flat sides of said first substrate
c) Curing said first adhesive
d) Applying a second adhesive at least partially onto at least one of the flat sides of said first or second substrate
e) Bonding said substrates to form said disc shaped workpiece.

2. Method according to claim 1, further comprising the step of
f) Curing said disc shaped workpiece

3. Method according to claim 1 or 2, wherein the first adhesive is adapted to provide good replication properties

4. Method according to claim 1 to 3, wherein the second adhesive is adapted to provide good elastic properties.
